(19) United States
(12) Patent Application Publication
(10) Pub. No.: US 2010/0200393 A1
(43) Pub. Date: Aug. 12, 2010

(54) SPUTTER DEPOSITION METHOD AND SYSTEM FOR FABRICATING THIN FILM CAPACITORS WITH OPTICALLY TRANSPARENT SMOOTH SURFACE METAL OXIDE STANDOFF LAYER

(76) Inventors: Robert Chow, Livermore, CA (US); Alan Ellis, Livermore, CA (US)

Correspondence Address: Lawrence Livermore National Security, LLC, LAWRENCE LIVERMORE NATIONAL LABORATORY, PO BOX 808, L-703, LIVERMORE, CA, 94551-0808, US

(21) Appl. No.: 12/703,113

(22) Filed: Feb. 9, 2010

Related U.S. Application Data
(60) Provisional application No. 61/151,106, filed on Feb. 9, 2009.

(51) Int. Cl. C23C 14/35; C23C 14/34

(52) U.S. Cl. 204/192.13; 204/192.15; 204/298.03; 204/298.07

(57) ABSTRACT

A sputter deposition method and system for producing a metal oxide film, especially a dielectric standoff layer of a thin film/nanolayer capacitor. A noble gas, such as argon, is used to sputter metal ions from a metal target, such as niobium, in the presence of a partial pressure of oxygen in a vacuum chamber. And an oxygen-to-noble gas flow ratio entering the vacuum chamber is controlled by a flow controller to be within an operating range defined between a predetermined lower limit (such as 30% O₂/Ar for niobium oxide) associated with a minimum transparency/stoichiometric threshold and a predetermined upper limit (such as 80% O₂/Ar for niobium oxide) associated with a maximum roughness/porosity threshold, so that a reaction between the sputtered metal ions and the oxygen produces a substantially transparent metal oxide film with a substantially smooth non-porous surface.

### CLAIM OF PRIORITY IN PROVISIONAL APPLICATION

This application claims priority in provisional application filed on Feb. 9, 2009, entitled “Fabrication and Characterization of Nanolayer Capacitors” Ser. No. 61/151,106, by Robert Chow et al, and incorporated by reference herein.

### FEDERALLY SPONSORED RESEARCH OR DEVELOPMENT

The United States Government has rights in this invention pursuant to Contract No. DE-AC52-07NA27344 between the United States Department of Energy and Lawrence Livermore National Security, LLC for the operation of Lawrence Livermore National Laboratory.

### FIELD OF THE INVENTION

The present invention relates to thin film capacitors and sputter deposition methods, and more particularly to a sputter deposition method and system for fabricating thin film/nanolayer capacitors having a substantially transparent metal oxide standoff layer with a substantially smooth non-porous surface produced, by sputtering a target metal with a noble process gas while controlling an oxygen-to-noble process gas flow ratio to be between a predetermined lower limit associated with a minimum transparency/stoichiometric threshold and a predetermined upper limit associated with a maximum roughness/porosity threshold.

### BACKGROUND

Sputtering is a well known physical vapor deposition process that has been used to fabricate various types of thin film structures, including for example small thin film capacitors. Sputtering is performed in a vacuum chamber and uses a noble process gas, such as for example argon, as a plasma carrier medium for sputtering material from a target. To accomplish this, a high negative potential is applied across the target, causing the process gas ions to accelerate towards and collide with the target, and ejecting target material towards the substrate via momentum transfer. For magnetron sputtering in particular, this electric field is applied in the presence of a magnetic field to enhance the concentration of and confine the plasma ions near the target surface. And reactive sputtering is used to produce oxide coatings by performing the sputtering process in the presence of a partial pressure of oxygen to chemically react the sputtered target material with oxygen.

In the fabrication of thin film capacitors sputter deposition processing is typically integrated with shadow-masking to form the various layers of the capacitor, i.e. the electrodes and the dielectric standoff layer therebetween, in a thin profile. And the quality and electrical performance of the capacitor is often determined by the quality of the dielectric material and its ability to withstand high voltages and minimize the current leakage between the electrodes. A rough and porous dielectric standoff layer can provide sharp conductive points from the electrodes into the dielectric which enhance the electric fields and thereby decrease the voltage stand-off of the capacitor. In addition, because the dielectric layer is often at least an order of magnitude thicker than the electrodes, the columnar structure that is typical of physical vapor deposition processes can create irregular surface asperities in the deposited layer as it becomes thicker. Furthermore, current leakage is often caused by sub-stoichiometric oxides containing atomic sites that allow charged particles (electrons and holes) to diffuse through the dielectric layer. The dielectric molecules at the interface of a free surface can absorb undesirable impurities such as water. Such impurities can break down the surface into sub-stoichiometric oxides or provide additional sites for charge transport. Charged particles can then also move along surface states and discharge the capacitor. Sub-stoichiometric oxides are also often visually discernible, with the best oxides being more optically transparent and less absorbing than poor quality oxides.

It would therefore be advantageous to provide a sputter deposition method and system of fabricating quality metal oxides, and thin film capacitors incorporating such metal oxides, that are fully oxidized (chemically stoichiometric), substantially optically transparent, and substantially smooth and non-porous to improve their electrical performance when used and formed as part of a thin film capacitor.

### SUMMARY OF THE INVENTION

One aspect of the present invention includes a sputter deposition method for producing a metal oxide film comprising: in a vacuum chamber, using a noble gas to sputter metal ions from a metal target in the presence of a partial pressure of oxygen; and controlling an oxygen-to-noble gas flow ratio entering the vacuum chamber to be within an operating range defined between a predetermined lower limit associated with a minimum transparency/stoichiometric threshold, and a predetermined upper limit associated with a maximum roughness/porosity threshold, so that a reaction between the sputtered metal ions and the oxygen produces a substantially transparent metal oxide film with a substantially smooth non-porous surface.

Another aspect of the present invention includes a sputter deposition system for producing a metal oxide film comprising: a vacuum chamber; a substrate mount for mounting a substrate in the vacuum chamber; a noble gas inlet for supplying noble gas to the vacuum chamber; an oxygen inlet for supplying oxygen to the vacuum chamber; a magnetron arranged in the vacuum chamber to use noble gas from the noble gas inlet to sputter metal ions from a metal target in the presence of a partial pressure of oxygen; and a flow controller for controlling an oxygen-to-noble gas flow ratio entering the vacuum chamber to be within an operating range defined between a predetermined lower limit associated with a minimum transparency/stoichiometric threshold and a predetermined upper limit associated with a maximum roughness/porosity threshold, so that a reaction between the sputtered metal ions and the oxygen produces a substantially transparent metal oxide film on the substrate with a substantially smooth non-porous surface.

Another aspect of the present invention includes a method of fabricating a thin film capacitor, comprising: in a vacuum chamber, using a noble gas to sputter metal ions from a metal target to form a first electrode layer on a substrate; in the vacuum chamber, using a noble gas to sputter metal ions from a metal target in the presence of a partial pressure of oxygen while controlling an oxygen-to-noble gas flow ratio entering the vacuum chamber to be within an operating range defined between a predetermined lower limit associated with a minimum transparency/stoichiometric threshold and a predetermined upper limit associated with a maximum roughness/porosity threshold, so that a reaction between the sputtered metal ions and the oxygen produces a substantially transparent metal oxide film with a substantially smooth non-porous surface; and in the vacuum chamber, using a noble gas to sputter metal ions from a metal target to form a second electrode layer on the metal oxide film, whereby the metal oxide film and the first and second electrode layers form a thin film capacitor.

Generally, the present invention is a sputter deposition method and system for fabricating substantially fully oxidized, substantially optically transparent, and substantially smooth non-porous metal oxide thin films, as well as a method and system for fabricating thin film capacitors (e.g. nanolayer capacitors with profiles on the order of a micron/nF) having such quality metal oxide films formed by sputter deposition and shadow masking. In particular, a metal target material, such as for example niobium, is sputtered in a vacuum chamber using a noble process gas, such as for example argon, and in the presence of a partial pressure of oxygen to react with the oxygen. And an oxygen-to-noble gas flow ratio entering the vacuum chamber (which is a process parameter independent of the pressure regime, and magnetron current and voltage settings) is controlled to be within an operating range defined between a predetermined lower limit and a predetermined upper limit. In an exemplary embodiment, an oxygen mass flow controller is used to control the oxygen-to-noble gas flow ratio by controlling the flow of oxygen only while the noble gas flow is held constant. However, it is appreciated that mass flow control of one or both of the noble gas and oxygen flows may be controlled so as to keep the oxygen-to-noble gas flow ratio within the range set by the predetermined upper and lower limits.

The oxygen-to-noble gas flow ratio and the control thereof between the lower and upper limits, are key process parameters of the present invention and important drivers of capacitor performance. In particular, the predetermined lower limit is associated with a minimum transparency/stoichiometric threshold, and the predetermined upper limit is associated with a maximum roughness/porosity threshold, so that a reaction between the sputtered metal ions and the oxygen produces a substantially transparent metal oxide film with a substantially smooth non-porous surface. A quality oxide coating is possible because the predetermined lower limit ensures that a sufficient supply of oxygen is available for a chemically stoichiometric reaction of the metal oxide (i.e. fully oxidized). And the predetermined upper limit prevents excessive oxygen flow from causing a rough porous surface so as to minimize particulation and material defect generation in the capacitive device, which can cause current leakage and reduction in voltage breakdown strength as discussed in the Background.

In a preferred embodiment of the invention, the selected metal target is niobium, and the selected noble gas (for use as the sputtering or process gas) is argon. Niobium oxide is a material with a high dielectric constant of 40, which makes it a good candidate for making high-energy-density capacitors. It also has a high refractive index, wide band gap, and superior chemical and thermal stability. It is appreciated, however, that other target metals such as for example Ta and Vd may be utilized to form other metal oxides deposited by reactive sputtering. And while argon is preferably selected as the process gas for sputtering niobium, it is appreciated that other noble gases, such as krypton and xenon for example, may be utilized for sputtering Niobium or other target materials.

For producing niobium oxide using argon as the noble gas, the predetermined lower and upper limits of the operating range of the oxygen-to-argon flow ratio are about 30% and about 80%, respectively. For ratios less than about 0.30, it has been determined that the niobium oxide is absorbing and substoichiometric (See FIGS. 3 and 4). And at ratios greater than about 0.80, the niobium oxide coating was determined to be rough and porous. Within the process space of greater than about 30% and less than about 80%, capacitors made at target voltages less than 600 V were shown to have lower dissipation factors (see FIG. 6).

Furthermore, the sputter deposition method and system of the present invention may additionally include the use of a plasma emission monitor (PEM) for monitoring the plasma intensity of the sputtered metal ions in the vacuum chamber, and actively controlling the oxygen-to-noble gas flow ratio so that the monitored plasma emission intensity of the sputtered metal ions remains within an operating range defined between a predetermined lower limit associated with a maximum metal target poisoning threshold without completely poisoning the metal target, and a predetermined upper limit associated with the minimum transparency/stoichiometric threshold. As described above, control of the oxygen-to-noble gas flow ratio may be achieved by controlling at least one of an oxygen flow controller and a noble gas flow controller. Moreover, it is appreciated that reference to a “flow controller for controlling the oxygen-to-noble gas flow ratio” may also be embodied as one or more of the oxygen flow controller and noble gas flow controller.

### BRIEF DESCRIPTION OF THE DRAWINGS

The accompanying drawings, which are incorporated into and form a part of the disclosure, are as follows:

FIG. 1 is a schematic view of an exemplary embodiment of the sputter deposition system of the present invention, and showing a vacuum chamber with three targets/guns, a plasma emission monitor, and an O₂ mass flow controller for controlling the oxygen/process gas flow ratio.

FIG. 2 is a schematic view of the reactive sputtering process of the present invention with oxygen-to-argon flow ratio control and integrated with shadow masking.

FIG. 3 is a graph of a reactive sputtering hysteresis curve using manual control and a plasma emission monitor to establish oxygen flows for transparent niobium oxide coatings, and illustrates the determination of a lower limit for the oxygen flow rate and oxygen-to-noble gas flow ratio.

FIG. 4 is a graph of a spectrophotometric transmission scans of three example niobium oxides produced on glass slides, and illustrating transparency differences based on various PEM set points (e.g. normalized Nb plasma intensities).

FIG. 5 is a graph showing exemplary niobium oxide breakdown voltages determined in a target voltage and oxygen-to-noble gas flow ratio process space.

FIG. 6 is a graph showing exemplary niobium oxide dissipation factors determined in a target voltage and oxygen-to-noble gas flow ratio process space.

### DETAILED DESCRIPTION

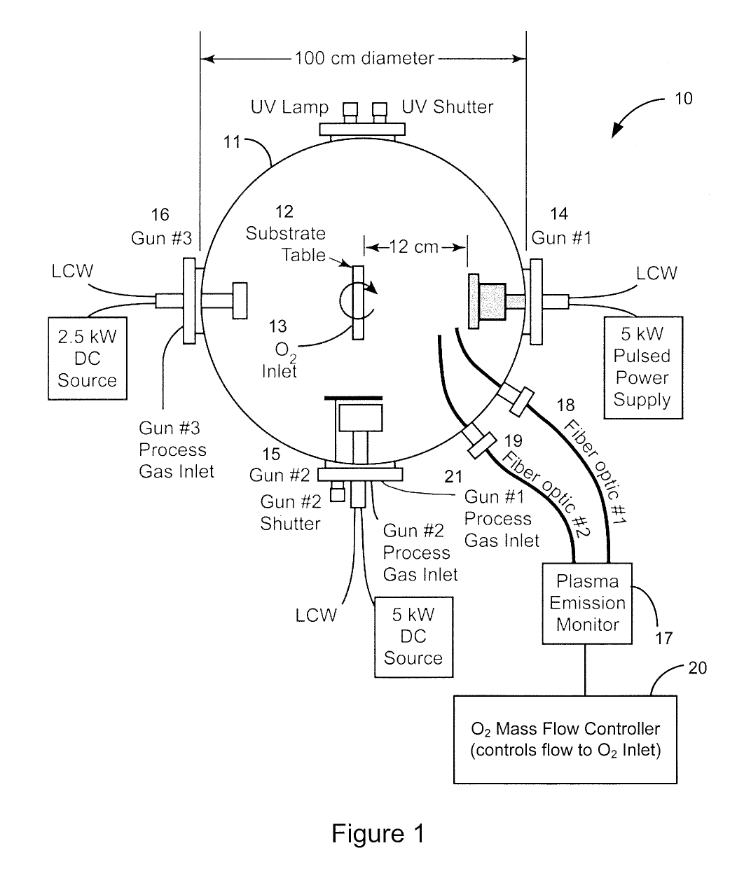

Turning now to the drawings, FIG. 1 shows a first exemplary embodiment of a sputter deposition system of the present invention, generally indicated at 10, and generally having a vacuum chamber 11 (e.g. with stainless steel construction); multiple sputtering sources shown as magnetron guns 14-16 with associated power supplies, noble process gas inlets, and noble gas flow controllers (not shown); and a substrate and mask assembly generally 12 shown mounted concentrically inside the chamber center and rotated to one of the three magnetron guns 14-16 for the desired material to be sputtered. Cryo- and turbopumps (not shown) are also provided to achieve low base pressures. In one example embodiment, a base pressure of 3.3 mPa (4.4×10⁻⁷ Torr) was used, and the sputter pressures were set to 0.4 (3.0) and 0.93 (7.0) Pa (mTorr) for the metal (e.g. Cu) and oxide (e.g. niobium oxide) depositions, respectively.

Of the three sputtering sources shown in FIG. 1, sputter source 14 is a reactive sputter source used for sputtering target metal to react with oxygen to produce an oxide coating, and is preferably a rotating magnetron built with a rotating magnet array (e.g. at 480 rpm) including a metal target 14′ and a pulsed power supply. The rotating magnet array increases the material utilization of the target and the thickness uniformity of the coating. Noble gas inlet 21 is associated with metal target 14′ but is shown at a different location from the metal target 14′. Oxygen is supplied to the vacuum chamber 11 near the substrate via oxygen inlet 13 shown as part of the substrate and mask assembly 12. And an oxygen mass flow controller is provided at 20 to control the oxygen flow rate entering the vacuum chamber at the oxygen inlet 13. The other two sputter sources 15 and 16 may be standard magnetron sputter sources for sputtering metals without oxidation, to form electrodes for example.

A plasma emission monitor (PEM) is also provided at 17 in FIG. 1 and shown with two fiber optic lines 18, 19 connected into the vacuum chamber for monitoring the reactive sputtering process therein. In particular, the PEM may be used to monitor respective plasma emission intensities of the metal target ions sputtered from the metal target 14′ and noble gas plasma generated from the noble gas inlet 21. One of the fiber optic lines, such as 19, collects light from the noble gas ions and the other fiber optic line, such as 18, collects light from the sputtered target metal ions. The two intensities may be combined in a ratio to take out the variations of plasma intensity caused by the rotating magnet array (i.e. to normalize the sensed target metal plasma intensity). It is notable, however, that where normalization is unnecessary or otherwise not performed, only one fiber optic line is required for the PEM, for sensing and monitoring the metal plasma wavelength only for purposes of the present invention.

As shown in FIG. 1, the PEM may also be used to actively control the O₂ mass flow controller 20 and oxygen flow into the vacuum chamber, so as to maintain the oxygen-to-noble gas flow ratio within the desired operating range between the predetermined lower and upper limits and an optimized oxygen-to-metal concentration for the oxidation reaction. The PEM may be integrated into the control loop of the oxygen mass flow controller so that, for example, oxides could be deposited in the oxygen flow regime of 27 sccm (35% oxygen-to-noble gas flow ratio) where the target is significantly, but not fully, oxidized.

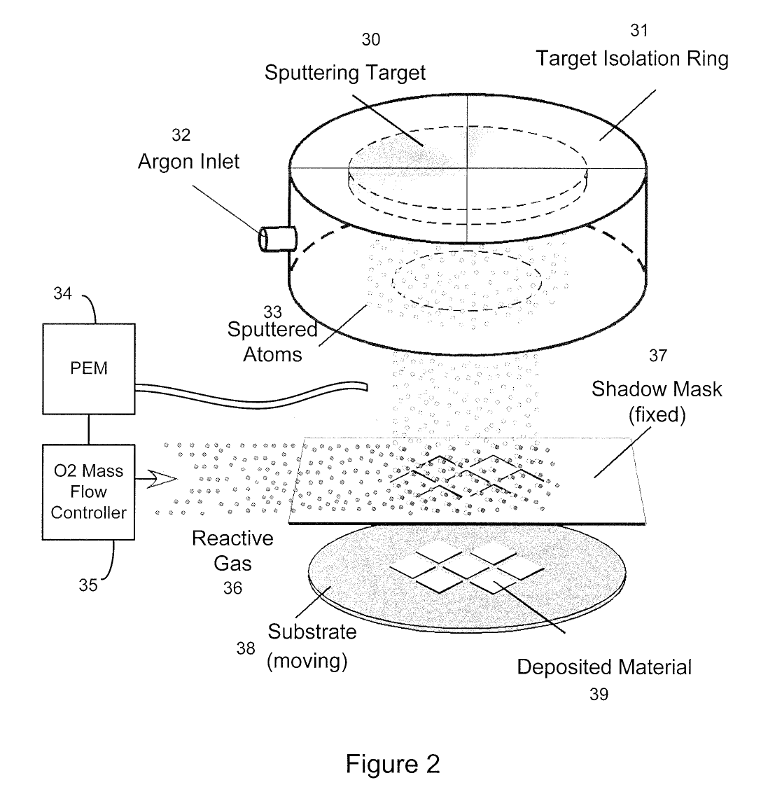

FIG. 2 is a schematic view of the reactive sputtering process of the present invention with oxygen-to-argon flow ratio control and integrated with shadow masking. A sputtering target 30 is shown surrounded by a target isolation ring 31 with argon inlet 32 injecting argon gas within the target isolation ring 31. In this way the target isolation ring baffles oxygen from the target, and minimize target poisioning. Sputtered atoms 33 from the sputtering target are then emitted through an opening in the target isolation ring, and towards the shadow mask 37. A PEM 34 is shown monitoring the intensity of the sputtered atoms and is operably connected to an oxygen mass flow controller 35 to control the mass flow of oxygen on the target-side of the shadow mask. The shadow mask is situated between the magnetron source and the substrate, and defines the geometry of the deposited material 39 formed on the substrate 38. To separate electrode and dielectric layers, the substrate may be translated linearly with respect to the shadow mask.

With the sputtering setup shown in FIGS. 1 and 2, reactive sputter deposition of the present invention begins by sputtering the metal target material, such as for example niobium, using a noble process gas and in the presence of a partial pressure of oxygen to react with the oxygen. And an oxygen-to-noble gas flow ratio entering the vacuum chamber is controlled, such as with the oxygen mass flow controller, to be within an operating range defined between a predetermined lower limit and a predetermined upper limit. In an exemplary embodiment, an oxygen mass flow controller is used to control the oxygen-to-noble gas flow ratio by controlling the flow of oxygen only while the noble gas flow is held fixed.

The purpose of establishing the predetermined lower limit is to supply sufficient oxygen for a chemically stoichiometric reaction of the metal oxide (i.e. fully oxidized). Sub-stoichiometric oxides are also often visually discernible, with the best oxides being more optically transparent and less absorbing than poor quality oxides. FIG. 4 is a graph of a spectrophotometric transmission scans of three example niobium oxides produced on glass slides, and illustrating transparency differences based on various PEM set points (e.g. normalized Nb plasma intensities). For example, the gray color of a niobium oxide dielectric is a visible indication of being sub-stoichiometric, and not fully oxidized. As discussed in the Background, sub-stoichiometric oxides allow charged particles (electrons and holes) to diffuse through the dielectric layer and cause current leakage and capacitor discharge.

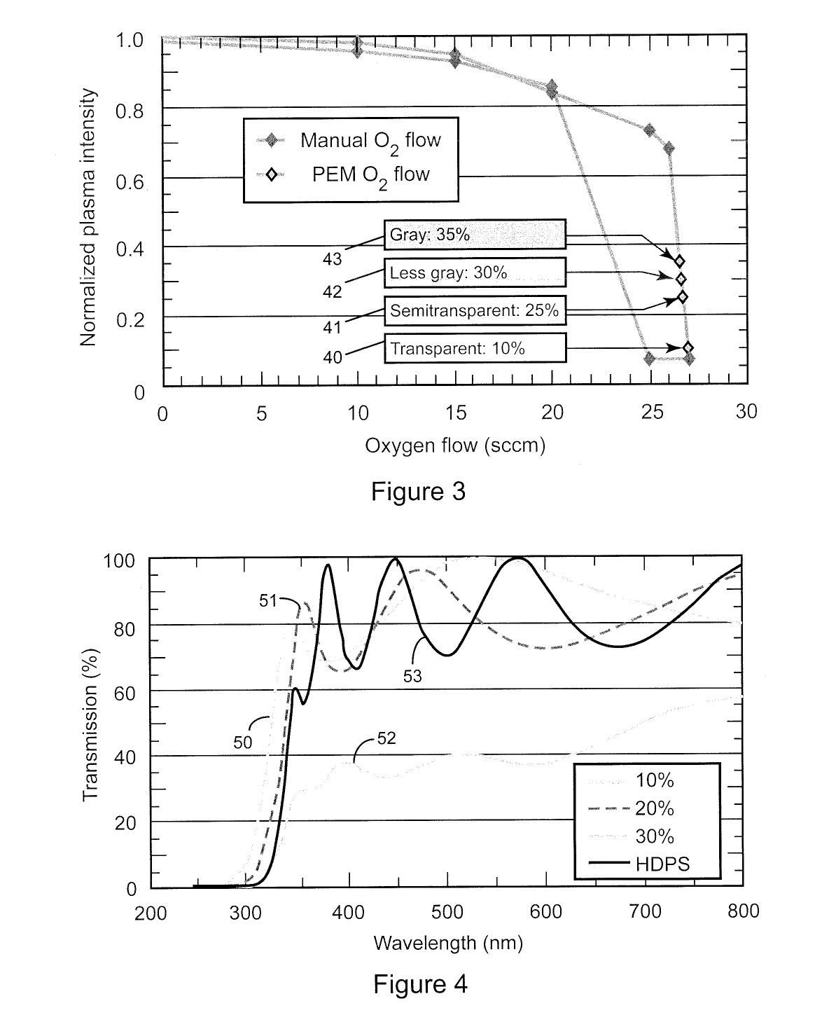

The PEM system 17 may use used to determine the minimum oxygen flow required to produce the best oxide, i.e. determine the minimum oxygen-to-argon flow ratio for non-absorbing niobium oxides. FIG. 3 shows the reactive sputtering hysteresis curve of plasma emission intensity as a function of oxygen flow from Nb deposition. The lower limit may be determined of the oxygen-to-noble gas flow ratio (e.g. 30% determined from FIG. 3 based on a lower limit of about 23 sccm oxygen flow with 77 sccm argon flow). In reactive sputtering, an oxygen partial pressure regime can be established with the deposition rate vs. reactive gas flow technique. FIG. 3 also shows the transparency results of four oxide coatings reactively sputtered (open diamonds) using feedback control from the PEM, the visual quality of the oxides is annotated in FIG. 3, showing that the best oxide, as defined by transparency in the visible regime, is nearly the same as sputtering the niobium target in a fully oxidized state. As can be seen in FIG. 3, at zero oxygen flow, the target is in the condition of sputtering with a metallic deposition rate. As the oxygen flow increases from zero to 27 sccm (filled diamonds), the target is slowly oxidized, the oxidized area encroaches into the surface for metallic sputtering, and the ejected niobium metal concentration decreases, as indicated by a decrease in the plasma intensity from 1.0 to 0.7. At an oxygen flow of around 27 sccm, there is a rapid decrease in the normalized plasma intensity from 0.7 to <0.1. This “0.1” target condition is called the “fully” oxidized state. The target recovers to the metallic state if one decreases the oxygen flow to zero as indicated in the figure.

And the purpose of establishing the predetermined upper limit is to minimize particulation and material defect generation in the capacitive device, which can cause current leakage, and reduction in voltage breakdown strength as discussed in the Background. If one does not consider the detrimental effect of excessive concentration of the reactive gas one would follow the logic to supply an abundance of oxygen to drive the oxidation reaction to completion by increasing the oxidation probability at the deposited, growing surface. (Logic would dictate that an excessive oxygen concentration would help drive the oxidation reactions by increasing the oxidation probability at the surface.) This approach has been used successfully in reaction electron beam evaporation of metal oxides, and in molecular beam epitaxy of III-V compounds. The reason this reactive deposition methodology works is that the higher vapor pressure material, oxygen for making oxides and As for GaAs epitaxy, have near-zero sticking coefficient on the surface once the oxide or III-V compound is formed.

However, an excessive oxygen concentration actually degrades the electrical qualities and the surface morphologies. An upper bound also exists for high quality capacitors built by a physical vapor deposition process, and the present invention incorporates this upper bound in controlling the reactive sputtering process. Excessive oxygen concentration degraded both of the electrical capacitive qualities, the breakdown voltage and dissipation factor (leakage current). Therefore, excessive oxygen causes the surface to roughen and creates pores. This is because excessive amounts of oxygen surrounding a metal on the surface reacts with the metal to form the oxide but the remaining, unreacted oxygen does not have sufficient time to diffuse out of the way of the incoming metal and other oxygen molecules. The residual oxygen is buried in the growing layer, forming pores within the dielectric layer that provide surface conduction paths for charge transport between the electrodes. The roughness of the dielectric coating also increases because the pores seed the irregularities that the columnar structure amplifies as the layer grows. One feature of the dielectric layer that is required to sustain high voltages is material smoothness. The dielectric layer is at least an order of magnitude thicker than the electrodes. As the deposited layer becomes thicker, the columnar structure, typical of physical vapor deposition processes, creates the irregular surface asperities. Rough dielectric layers acts as sharp conductive points from the electrodes into the dielectric. The sharp points enhance the electric fields and thereby decrease the voltage stand-off of the capacitor. Therefore, the present invention provides an upper bound for the oxygen concentration, and one must therefore use as low an oxygen concentration possible without causing the oxide to be gray (visibly sub-stoichiometric).

In experiments performed by Applicants in research performed at the Lawrence Livermore National Laboratory, the electrical characteristics of single-stack capacitors were determined as a function of target voltage and the oxygen-to-argon flow ratio, to evidence how the electrical performance of a capacitor is linked intrinsically to the quality of the dielectric. Oxygen to argon flow ratios were used to determine the upper bound of the reactive vapor concentration. Two sputtering process variables were selected to make single-layer capacitors for electrical characterization. One variable is the amount of oxygen, represented by the oxygen-to-argon flow ratio. From FIG. 3, the minimum ratio is 0.30, and we chose the maximum ratio of 1.0 and a middle ratio of 0.72. The motivation for increasing the oxygen flow (concentration) is to assure as complete an oxidation as possible of the Nb metal species arriving at the substrate. The other variable is the target voltage, which was changed by the power set point. The motivation here is to increase the average energy of the reaction species, oxygen and Nb, to again assure as complete an oxidation as possible at the surface of the substrate.

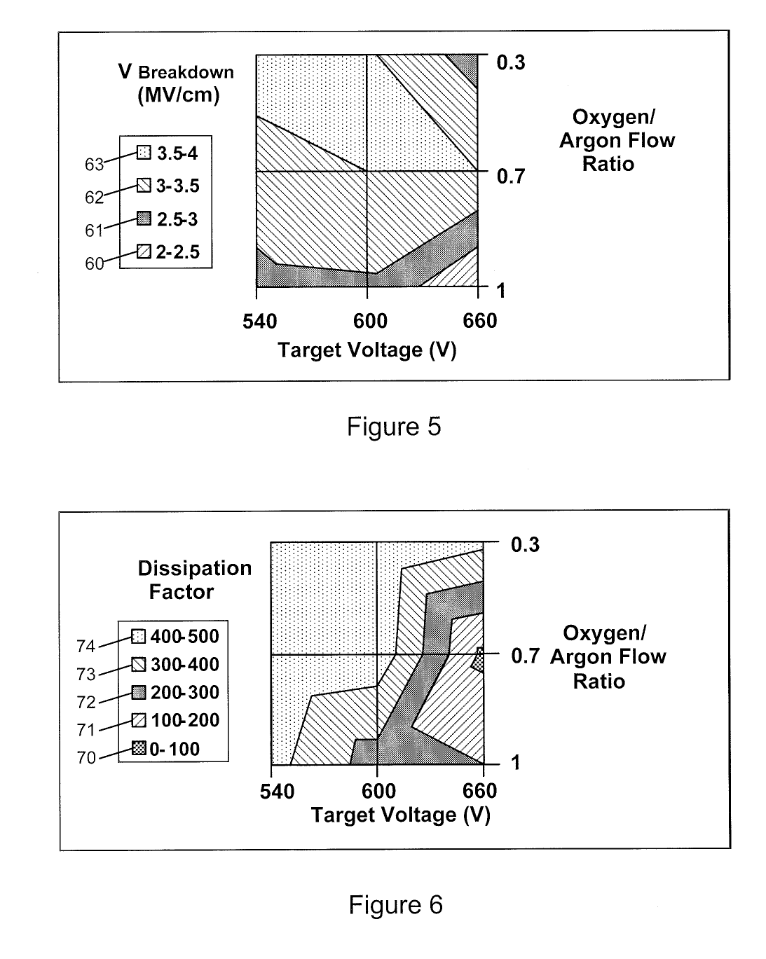

Single-stack capacitors were made in the process space described above for electrical characterization. The field strength and dissipation factor are given in Tables 2 and 3, respectively. Also, FIG. 5 is a graph showing exemplary niobium oxide breakdown voltages determined in a target voltage and oxygen-to-noble gas flow ratio process space. And FIG. 6 is a graph showing exemplary niobium oxide dissipation factors determined in a target voltage and oxygen-to-noble gas flow ratio process space.

Table 1 in particular shows capacitor field strength (MV/cm) as a function of target voltages and _{O2}/Ar gas flow ratios. And Table 2 shows dissipation factor (mD) as a function of target voltage and _{O2}/Ar gas flow ratio.

TABLE 1

| O₂/Ar flow ratio | 540 V | 600 V | 660 V |
|---|---|---|---|
| 0.30 | 3.70 | 3.57 | 2.79 |
| 0.72 | 3.30 | 3.50 | 3.51 |
| 1.00 | 2.88 | 2.95 | 2.00 |

TABLE 2

| O₂/Ar flow ratio | 540 V | 600 V | 660 V |
|---|---|---|---|
| 0.30 | 14.5 | 13.2 | 81.2 |
| 0.72 | 16.2 | 37.7 | 422 |
| 1.00 | 70.4 | 246 | 300 |

Note that the higher field strengths and lower dissipation factors occur at the lower target voltages (540 V) and lower gas ratios (0.3). The reason for the degraded electrical properties at the high gas ratios was obvious by visual inspection. An excess of gas pressure produced oxide layers that scattered light from the roughened surface of the dielectric. Rough surfaces contain asperities that lead to low-voltage breakdowns. A rough surface is indicative of higher porosities and surface areas within the coating. This may contribute to higher dissipation factors because of increased conduction paths along these internal surfaces.

For a given gas flow ratio, electrical performance improves as the oxide deposition rate decreases. One explanation may be that at the low deposition rates, there is more time for the oxidation reaction to occur before the next population of sputtered metal atoms arrives. There is also more time for surface atoms to diffuse and bind in positions of lower energy states. The oxide may be more stoichiometric and stable. Other process variables that can affect field strengths are magnetron arcing and cleanliness. Arcing and a heavily coated magnetron tend to spew out debris into the substrate. The debris grows laterally in size with the coating thickness and becomes a likely breakdown path. This type of seeding defect may be more prevalent during high deposition rates.

A particular run of single-stack capacitors produced 35 capacitors with an average capacitance of 5.3±0.9 nF and an average dissipation factor of 5.3±1.4 mD. In this run, a capacitor had a maximum breakdown electric field strength of 4.8 MV/cm and an energy density of 31.8 Joules/cc.

While particular operational sequences, materials, parameters, and particular embodiments have been described and or illustrated, such are not intended to be limiting. Modifications and changes may become apparent to those skilled in the art, and it is intended that the invention be limited only by the scope of the appended claims.

We claim:

1. A sputter deposition method for producing a metal oxide film comprising:
in a vacuum chamber, using a noble gas to sputter metal ions from a metal target in the presence of a partial pressure of oxygen; and
controlling an oxygen-to-noble gas flow ratio entering the vacuum chamber to be within an operating range defined between a predetermined lower limit associated with a minimum transparency/stoichiometric threshold, and a predetermined upper limit associated with a maximum roughness/porosity threshold, so that a reaction between the sputtered metal ions and the oxygen produces a substantially transparent metal oxide film with a substantially smooth non-porous surface.

2. The sputter deposition method of claim 1,
wherein the metal target is niobium, the noble gas is argon, and the predetermined lower and upper limits of the operating range of said oxygen-to-noble gas flow ratio are about 30% and about 80%, respectively.

3. The sputter deposition method of claim 1, further comprising:
monitoring plasma emission intensity of the sputtered metal ions in the vacuum chamber; and
controlling the oxygen-to-noble gas flow ratio so that the plasma emission intensity of the sputtered metal ions is within an operating range defined between a predetermined lower limit associated with a maximum metal target poisoning threshold without completely poisoning the metal target, and a predetermined upper limit associated with the minimum transparency/stoichiometric threshold.

4. The sputter deposition method of claim 3,
wherein the metal target is niobium, the noble gas is argon, and the predetermined lower and upper limits of the operating range of the plasma emission intensity of the sputtered metal ions are about 10% and about 35%, respectively.

5. The sputter deposition method of claim 1, further comprising:
forming a first electrode layer on a substrate, forming the metal oxide film on the first electrode layer, and forming a second electrode layer on the metal oxide film, so as to form a thin film capacitor.

6. A sputter deposition system for producing a metal oxide film comprising:
a vacuum chamber;
a substrate mount for mounting a substrate in the vacuum chamber;
a noble gas inlet for supplying noble gas to the vacuum chamber;
an oxygen inlet for supplying oxygen to the vacuum chamber;
a magnetron arranged in the vacuum chamber to use noble gas from the noble gas inlet to sputter metal ions from a metal target in the presence of a partial pressure of oxygen; and
a flow controller for controlling an oxygen-to-noble gas flow ratio entering the vacuum chamber to be within an operating range defined between a predetermined lower limit associated with a minimum transparency/stoichiometric threshold and a predetermined upper limit associated with a maximum roughness/porosity threshold, so that a reaction between the sputtered metal ions and the oxygen produces a substantially transparent metal oxide film on the substrate with a substantially smooth non-porous surface.

7. The sputter deposition system of claim 6,
wherein the metal target is niobium, the noble gas is argon, and the predetermined lower and upper limits of the operating range of said oxygen-to-noble gas flow ratio are about 30% and about 80%, respectively.

8. The sputter deposition system of claim 6, further comprising:
a plasma emission monitor for monitoring plasma emission intensity of the sputtered metal ions in the vacuum chamber, said plasma emission monitor operably connected to the flow controller to control the oxygen-to-noble gas flow ratio so that the plasma emission intensity of the sputtered metal ions is within an operating range defined between a predetermined lower limit associated with a maximum metal target poisoning threshold without completely poisoning the metal target, and a predetermined upper limit associated with the minimum transparency/stoichiometric threshold.

9. The sputter deposition system of claim 8,
wherein the metal target is niobium, the noble gas is argon, and the predetermined lower and upper limits of the operating range of the plasma emission intensity of the sputtered metal ions are about 10% and about 35%, respectively.

10. A method of fabricating a thin film capacitor, comprising:
in a vacuum chamber, using a noble gas to sputter metal ions from a metal target to form a first electrode layer on a substrate;
in the vacuum chamber, using a noble gas to sputter metal ions from a metal target in the presence of a partial pressure of oxygen while controlling an oxygen-to-noble gas flow ratio entering the vacuum chamber to be within an operating range defined between a predetermined lower limit associated with a minimum transparency/stoichiometric threshold and a predetermined upper limit associated with a maximum roughness/porosity threshold, so that a reaction between the sputtered metal ions and the oxygen produces a substantially transparent metal oxide film with a substantially smooth non-porous surface; and
in the vacuum chamber, using a noble gas to sputter metal ions from a metal target to form a second electrode layer on the metal oxide film,
whereby the metal oxide film and the first and second electrode layers form a thin film capacitor.

11. The method of fabricating the thin film capacitor of claim 10,
wherein the metal target is niobium, the noble gas is argon, and the predetermined lower and upper limits of the operating range of said oxygen-to-noble gas flow ratio are about 30% and about 80%, respectively.

12. The method of fabricating the thin film capacitor of claim 10,
wherein the step of controlling the oxygen-to-noble gas flow ratio in the production of the metal oxide film includes:
monitoring plasma emission intensity of the sputtered metal ions in the vacuum chamber; and
controlling the oxygen-to-noble gas flow ratio so that the plasma emission intensity of the sputtered metal ions is within an operating range defined between a predetermined lower limit associated with a maximum metal target poisoning threshold without completely poisoning the metal target, and a predetermined upper limit associated with the minimum transparency/stoichiometric threshold.

13. The method of fabricating the thin film capacitor of claim 12,
wherein the metal target is niobium, the noble gas is argon, and the predetermined lower and upper limits of the operating range of the plasma emission intensity of the sputtered metal ions are about 10% and about 35%, respectively.
